(19) United States
(12) Patent Application Publication
(10) Pub. No.: US 2017/0062689 A1
(43) Pub. Date: Mar. 2, 2017

(54) THERMOELECTRIC DEVICE AND THERMOELECTRIC SYSTEM INCLUDING THE DEVICE

(71) Applicant: PUSAN NATIONAL UNIVERSITY INDUSTRY-UNIVERSITY COOPERRATION FOUNDATION, Busan (KR)

(72) Inventor: Tae June KANG, Yangsan-si (KR)

(21) Appl. No.: 15/304,295

(22) PCT Filed: Apr. 13, 2015
(86) PCT No.: PCT/KR2015/003654

§ 371 Date: Nov. 11, 2016

(30) Foreign Application Priority Data
Apr. 17, 2014 (KR) 10-2014-0046209

(51) Int. Cl. H01L 35/30; H01L 35/32; F01P 3/20; H02S 10/30

(52) U.S. Cl. CPC H01L 35/30; H02S 10/30; H01L 35/32; F01P 3/20; F01P 2003/001

(57) ABSTRACT

In one aspect of the present disclosure, there is provided a thermoelectric device comprising: a closed-loop flow channel configured to allow a liquid electrolyte to circulate therein and therealong in one direction; an electrolyte flow activator configured to activate the liquid electrolyte circulation along the flow channel; a first electrode disposed at a first position of the flow channel; and a second electrode disposed at a second position of the flow channel, wherein the first and second positions are different, wherein the liquid electrolyte has a redox reaction due to a temperature difference between the first electrode and the second electrode.

### BACKGROUND

Field of the Present Disclosure

The present disclosure relates to a thermoelectric device and a thermoelectric system including the device. More particularly, the present disclosure relates to a thermoelectric device wherein a temperature difference between electrodes sandwiching an electrolyte solution allow the electrolyte solution to convert a thermal energy to an electrical energy, and to a thermoelectric system including thermoelectric device.

Discussion of Related Art

A thermoelectric device may exhibit a thermoelectric effect. The device may use Seebeck effect to use a temperature difference for electrical generation. The thermoelectric device has been widely used in various fields of space, airplane, semiconductor, power generation, etc.

Currently, the energy harvesting has been popular worldwide. In this connection, the thermoelectric device using the Seebeck effect to convert the waste thermal energy to the electrical energy has been focused on. Thermal batteries including, for example, thermogalvanic cells or thermal electrochemical cells may generate electrical energy based on a dependency of an electrochemical redox voltage of an electrolyte on a temperature. Such thermal batteries may have advantages of direct thermal-electrical energy conversion, simple configuration, semi-permanent durability, low maintenance cost, and no carbon-emission. Thus, the thermal batteries have been reported as the most effective technique for the energy harvesting using waste heat. In particular, mechanical flexibility and low production cost thereof may realize efficient absorption of waste heats from daily life below 100° C. Recently, thermoelectric devices using a thermoelectric electrolyte have been studied for improvement of power generation efficiency.

Further, a solar cell battery for the energy harvesting has been widely used. The solar cell may use a photovoltaic efficiency sensitive to an operating temperature. Thus, the high temperature may lower the photovoltaic efficiency. Thermal management and usage of the solar cell to deal with this issue may become one important element for a future solar cell development. For the Thermal management of the solar cell, air cooling or water cooling is employed. However, a performance recovery of the solar cell using the air cooling or water cooling may merely amount to about 10 to 30% of an initial performance thereof.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

The present disclosure is to provide a thermoelectric device having a flow cell structure for use as a cooling device for solar cell or vehicles or the like.

Further, the present disclosure is to provide a thermoelectric system including a thermoelectric device with a power generation together with a cooling function for solar cell or vehicles.

In one aspect of the present disclosure, there is provided a thermoelectric device comprising: a closed-loop flow channel configured to allow a liquid electrolyte to circulate therein and therealong in one direction; an electrolyte flow activator configured to activate the liquid electrolyte circulation along the flow channel; a first electrode disposed at a first position of the flow channel; and a second electrode disposed at a second position of the flow channel, wherein the first and second positions are different, wherein the liquid electrolyte has a redox reaction due to a temperature difference between the first electrode and the second electrode.

In one implementation, the thermoelectric device further comprises an electrolyte cooler configured to cool the liquid electrolyte.

In one implementation, the liquid electrolyte contains a hexacyanoferrate trivalent anion (Fe(CN)₆³⁻) and a hexacyanoferrate quadrivalent anion (Fe(CN)₆⁴⁻).

In one aspect of the present disclosure, there is provided a thermoelectric system comprising: a heat source; and a thermoelectric device thermally coupled to the heat source, wherein the thermoelectric device comprising:

a closed-loop flow channel configured to allow a liquid electrolyte to circulate therein and therealong in one direction, wherein the closed-loop flow channel is thermally-coupled to the heat source, an electrolyte flow activator configured to activate the liquid electrolyte circulation along the flow channel; a first electrode disposed at a first position of the flow channel; and a second electrode disposed at a second position of the flow channel, wherein the first and second positions are different, wherein the liquid electrolyte has a redox reaction due to a temperature difference between the first electrode and the second electrode.

In one implementation, the system further comprises an electrolyte cooler thermally coupled to the thermoelectric device to cool the liquid electrolyte.

In one implementation, the heat source is a solar cell, and the closed-loop flow channel acts to the solar cell using the liquid electrolyte.

In one implementation, the heat source is a vehicle engine, and the closed-loop flow channel acts to the engine using the liquid electrolyte.

In accordance with the present disclosure, a simple flow cell may be achieved using the thermoelectric device including the flow channel for the liquid electrolyte flow with a flexibility in the flow channel form. In this connection, at least one hot electrode and at least one cold electrode may be disposed at any positions of the flow channel. Thus, the liquid electrolyte may act to cool solar cell or vehicle engines, etc. in a liquid cooling manner.

Further, in the thermoelectric device, the temperature of the liquid electrolyte may be kept at a constant level. In the thermoelectric system, the thermoelectric device may be used not only as a cooler but also as a power generator.

### BRIEF DESCRIPTION OF THE DRAWINGS

The accompanying drawings, which are incorporated in and form a part of this specification and in which like numerals depict like elements, illustrate embodiments of the present disclosure and, together with the description, serve to explain the principles of the disclosure.

FIG. 1 illustrates a high level diagram of a flow-type thermoelectric device in accordance with one embodiment of the present disclosure.

FIG. 2A, FIG. 2B and FIG. 2C shows example configurations of thermoelectric device as described with reference to FIG. 1.

FIG. 3 illustrates a high level diagram of a thermoelectric system including a combination of a flow-type thermoelectric device and a heat source in accordance with one embodiment of the present disclosure.

FIG. 4A and FIG. 4B illustrates example structures of the thermoelectric system as described with reference to FIG. 3.

FIG. 5 illustrates a cross-sectional view of one example of a thermoelectric system including a solar cell as a heat source.

For simplicity and clarity of illustration, elements in the figures are not necessarily drawn to scale. The same reference numbers in different figures denote the same or similar elements, and as such perform similar functionality. Also, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

### DETAILED DESCRIPTIONS

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “connected to”, or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

Spatially relative terms, such as “beneath,” “below,” “lower,” “under,” “above,” “upper,” and the like, may be used herein for ease of explanation to describe one element or feature's relationship to another element s or feature s as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented for example, rotated 90 degrees or at other orientations, and the spatially relative descriptors used herein should be interpreted accordingly.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, s, operations, elements, and/or components, but do not preclude the presence or addition of one or more other features, integers, s, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present disclosure. The present disclosure may be practiced without some or all of these specific details. In other instances, well-known process structures and/or processes have not been described in detail in order not to unnecessarily obscure the present disclosure.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.”

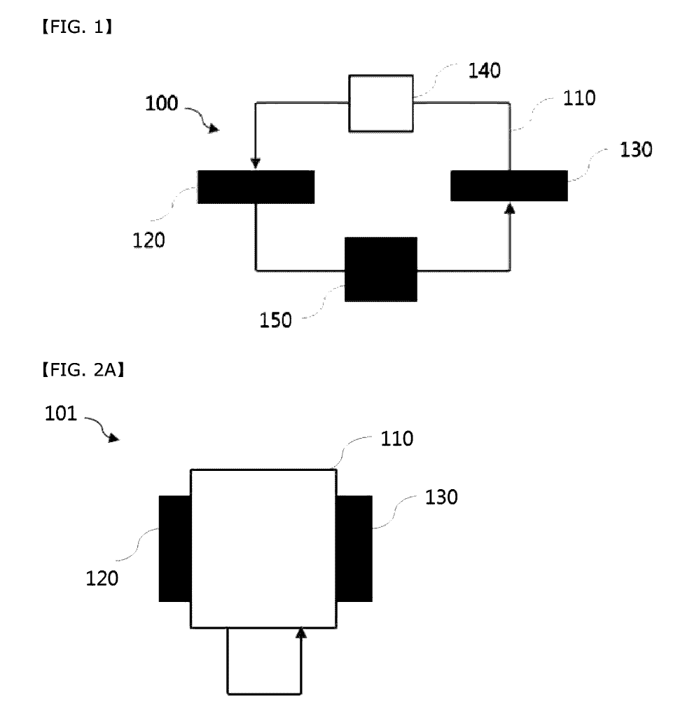

FIG. 1 illustrates a high level diagram of a flow-type thermoelectric device in accordance with one embodiment of the present disclosure.

Referring to FIG. 1, the thermoelectric device 100 may include a flow channel 110 for liquid electrolyte flow, and a first electrode 120 and a second electrode 130. A temperature difference between the first electrode 120 and the second electrode 130 may allow a redox reaction of the liquid electrolyte.

The flow channel 110 may allow the liquid electrolyte flow and may be disposed between the first electrode 120 and the second electrode 130. A shape of the flow channel 110 is not limited to a specific shape in the present disclosure. The flow channel 110 may have a pipe form for continuous flow of the liquid electrolyte. In an alternative, the flow channel 110 may have a box form for inner circulation of the liquid electrolyte.

The first electrode 120 may be disposed at a first position of the flow channel 110, while the second electrode 130 may be disposed at a second position of the flow channel 110 wherein the first and second positions are different. In one example, the first and second positions may be opposite in position thereof. That is, it may suffice that each of the first electrode 120 and the second electrode 130 contacts the liquid electrolyte in the flow channel 110. Thus, the contact position may not be limited to a specific position. One of the first electrode 120 and the second electrode 130 may act as a hot electrode with a higher temperature than that of the other electrode which, thus, act as a cold electrode. Hereafter, a reference is made to a case that the first electrode 120 acts as a hot electrode and the second electrode 130 acts a cold electrode.

When there occurs a temperature difference between the first electrode 120 and second electrode 130, an electrolyte in the liquid electrolyte adjacent to the first electrode 120 may be oxidized. Using the oxidation of the electrolyte, the first electrode 120 may receive an electron from the electrolyte and, thus, the electron may be supplied from the first electrode 120 to an external load coupled thereto to generate electric power. The electron may be supplied to the second electrode 130 via the external load coupled thereto. Thus, the second electrode 130 may supply the electron to the electrolyte to reduce the electrolyte. The redox reaction of the electrolyte may allow the liquid electrolyte to be kept at an electrically equilibrium state for continuous power generation.

For example, the liquid electrolyte may include a hexacyanoferrate trivalent anion (Fe(CN)₆³⁻) and hexacyanoferrate quadrivalent anion (Fe(CN)₆⁴⁻). The first electrode 120 may receive an electron resulting from generation of the hexacyanoferrate trivalent anion (Fe(CN)₆³⁻) and the second electrode 130 may receive the electron to reduce the same to the hexacyanoferrate quadrivalent anion (Fe(CN)₆⁴⁻).

The thermoelectric device 100 may include an electrolyte flow activator 140. The electrolyte flow activator 140 may be fluid-coupled to the flow channel 110 to activate the liquid electrolyte flow. For example, the electrolyte flow activator 140 may be implemented as a pump.

The thermoelectric device 100 may include an electrolyte cooler 150. The first electrode 120 may have increase in a temperature due to an external heat and the first electrode 120 may heat the liquid electrolyte. The heated liquid electrolyte may be cooled while passing through the electrolyte cooler 150. The cooled liquid electrolyte may be supplied to the second electrode 130. The electrolyte cooler 150 may be implemented as a heat dissipation device. One example thereof may be a heat radiator.

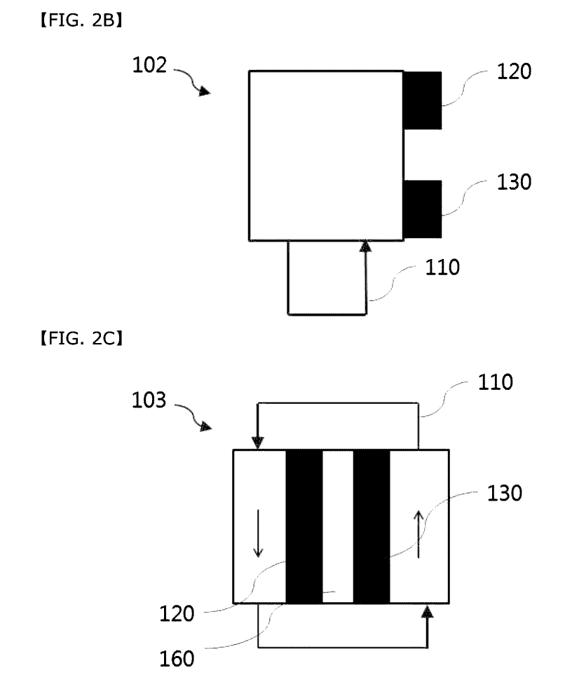

FIG. 2A, FIG. 2B and FIG. 2C shows example configurations of thermoelectric device as described with reference to FIG. 1.

The electrolyte flow activator 140 and electrolyte cooler 150 as described with reference to FIG. 1 may be fluid-coupled to the flow channel 110 in each of thermoelectric devices of FIG. 2A, FIG. 2B and FIG. 2C. With reference to FIG. 2A, FIG. 2B and FIG. 2C, an arrangements of the flow channel 110, the first and second electrodes 120, 130 will be described briefly. However, the present disclosure may not be limited thereto.

As for the thermoelectric device 101 as shown in FIG. 2A, the first electrode 120 and second electrode 130 may be disposed at both opposite positions of the flow channel 110 respectively. In one example, the first electrode 120 and second electrode 130 may be arranged in a position-aligned manner as shown in FIG. 2A. In an alternative, the first electrode 120 and second electrode 130 may be arranged in a position-non-aligned manner (not shown).

Further, as for thermoelectric device 102 as shown in FIG. 2B, the first electrode 120 and second electrode 130 may be arranged at one-sided positions of the flow channel 110 along a flow path of the liquid electrolyte.

The flow direction of the liquid electrolyte in FIG. 2A and FIG. 2B may be set such that the liquid electrolyte contacting the first electrode 120 is fed to the second electrode 130 and, then, the liquid electrolyte contacting the second electrode 130 is again fed to the first electrode 120. In this way, the first and second electrodes 120, 130 may be disposed at first and second different positions of the flow channel 110 respectively, thereby to form a simple flow cell.

Referring to FIG. 2C, the thermoelectric device 103 may include the flow channel 110, the first electrode 120, the second electrode 130 and a separator 160. The separator 160 may be interposed between the first electrode 120 and second electrode 130 to separate them. The separator 160 may allow an electrical insulation between the first and second electrodes 120, 130. The flow direction of the liquid electrolyte in FIG. 2C may be set such that the liquid electrolyte contacting the first electrode 120 is fed to the second electrode 130 and, then, the liquid electrolyte contacting the second electrode 130 is again fed to the first electrode 120.

Generally, as for thermoelectric device 100 of the present disclosure, a form of the flow channel 110 may not be limited to a specific form. Further, the arrangement of the first and second electrodes 120, 130 may be flexible. Further, in the thermoelectric device 100, the temperature of the liquid electrolyte may be kept at a constant level.

In this way, the liquid electrolyte may act to cool solar cell or vehicles in a liquid cooling manner. In addition, the liquid electrolyte flow may improve power generation efficiency of the thermoelectric device 100.

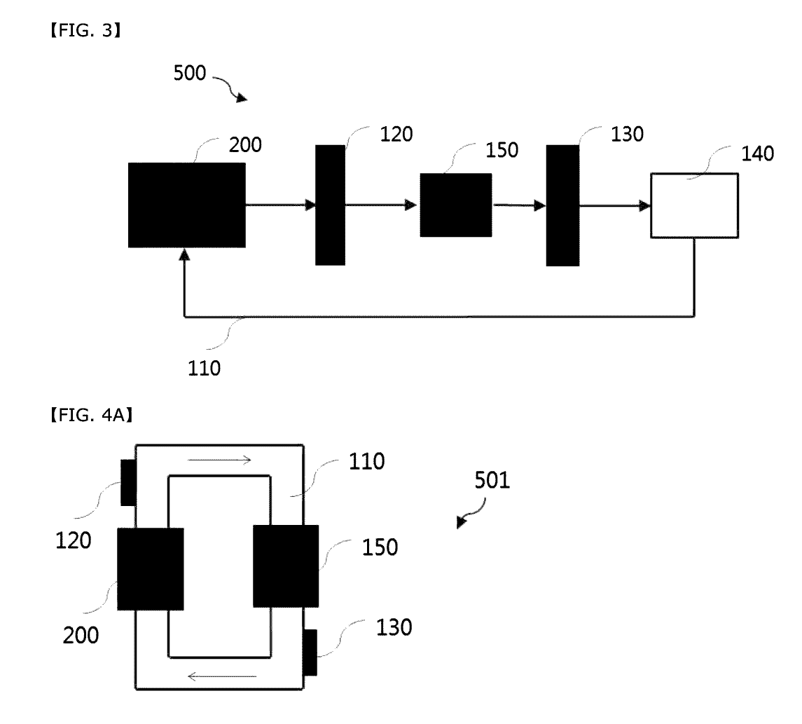

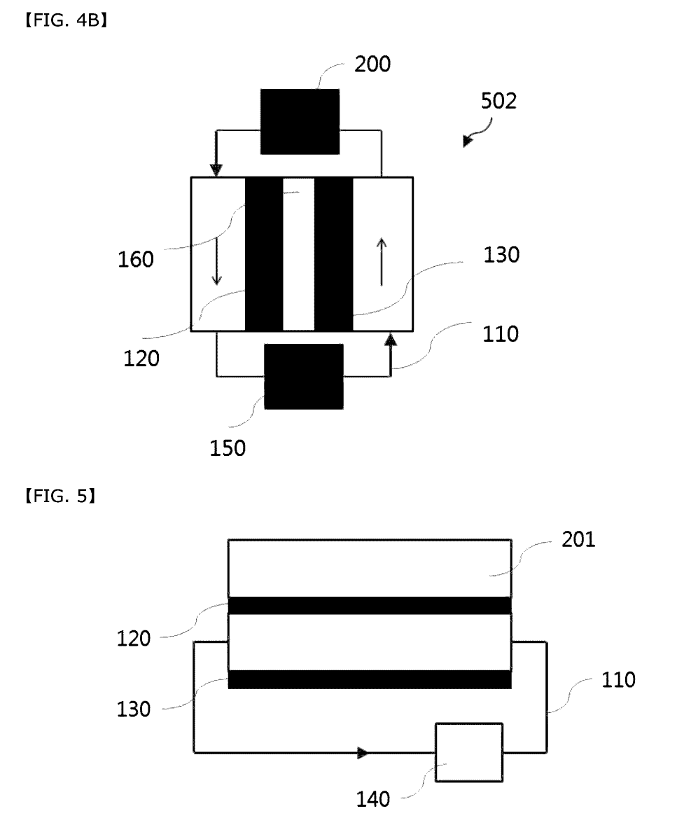

Hereinafter, with reference to FIG. 3, a thermoelectric system 500 where the thermoelectric device 100 of the present disclosure is applied will be described in details. Further, with reference to FIG. 4A and FIG. 4B, examples of the thermoelectric system 500 will be described in details.

FIG. 3 illustrates a high level diagram of a thermoelectric system including a combination of a flow-type thermoelectric device and a heat source in accordance with one embodiment of the present disclosure.

Referring to FIG. 3, the thermoelectric system 500 may include the thermoelectric device and the heat source 200 thermally coupled to the thermoelectric device. The thermoelectric device may include the flow channel 110, the first and second electrodes 120, 130 and the electrolyte flow activator 140. In this connection, the thermoelectric system 500 may further include an electrolyte flow activator 140 to enable the liquid electrolyte flow in the flow channel 110 and/or an electrolyte cooler 150 for the liquid electrolyte. Except the heat source 200, the components described above with reference to FIG. 1 will be omitted in descriptions thereof.

The heat source 200 may act as a heat source for the thermoelectric device. The heat source 200 may be configured to feed a heat to the first electrode 120 as a hot electrode. The heat source 200 may be adjacent to the first electrode 120 which, in turn, receives a heat from the heat source 200. The heat source 200 may refer to all kind of objects or devices capable of heat emission. Examples of the heat source 200 may include, only by way of example, solar cell, vehicle engine, etc. When the heat source 200 is the solar cell, or vehicle engine, the heat source 200 may emit a heat during an operation thereof. This heat as a waste heat may be fed to the thermoelectric device for energy harvesting.

The liquid electrolyte flowing along flow channel 110 may be heated at the first electrode 120 and, thus, may be oxidized or reduced. Thereafter, the liquid electrolyte may be cool at the electrolyte cooler 150 and then may be fed to the second electrode 130. When the liquid electrolyte contacts the second electrode 130, the liquid electrolyte may be reduced or oxidized. The cooled liquid electrolyte may be fed to the heat source 200 to cool the heat source 200. In this way, the liquid electrolyte may be used to cool the heat source 200. At the same time, the thermoelectric device may generate power using the temperature difference between the first electrode 120 and the second electrode 130.

FIG. 4A and FIG. 4B illustrates example structures of the thermoelectric system as described with reference to FIG. 3.

The electrolyte flow activator 140 as described with reference to FIG. 3 may be fluid-coupled to the flow channel 110 in FIG. 4A or FIG. 4B. With reference to FIG. 4A and FIG. 4B, arrangements of the thermoelectric device and heat source 200 will be described briefly. However, the present disclosure may not be limited thereto.

As for the thermoelectric system 501 as shown in FIG. 4A, the heat source 200 and electrolyte cooler 150 may be coupled to the flow channel 110, and the first electrode 120 and second electrode 130 may be disposed at different positions of the flow channel 110. The first electrode 120 and second electrode 130 may be disposed at any different positions of the flow channel 110.

In one example, the first electrode 120 as a hot electrode may be adjacent to the heat source 200 to heat the liquid electrolyte using the heat from the heat source 200. The shorter a distance between the first electrode 120 and heat source 200 is, the higher the temperature of the first electrode 120 is.

The second electrode 130 as the cold electrode may be adjacent to the electrolyte cooler 150 such that the liquid electrolyte is cooled by the electrolyte cooler 150 and, thereafter, is fed to the second electrode 130. The shorter a distance between the second electrode 130 and electrolyte cooler 150 is, the lower the temperature of the second electrode 120 is. In this way, the temperature difference between the first electrode 120 and second electrode 130 may be maximized.

As for the thermoelectric system 502 as shown in FIG. 4B, the heat source 200 and electrolyte cooler 150 may be coupled to the flow channel 110, and the first electrode 120 and second electrode 130 may be disposed at different positions of the flow channel 110. The first electrode 120 and second electrode 130 may be separated by the separator 160.

The liquid electrolyte heated using a heat from the heat source 200 may contact the first electrode 120 as a hot electrode. Thereafter, the liquid electrolyte may pass through the electrolyte cooler 150 to the second electrode 130. Thus, the cooled liquid electrolyte may be fed to the second electrode 130 and thereafter may be fed to the heat source 200 to cool the heat source 200.

In the thermoelectric system 500 of the present disclosure, a form of the flow channel 110 may not be limited to the specific form. The arrangement of the first and second electrodes 120, 130 may be flexible. Thus, a connection between the heat source 200 and thermoelectric device may be easy. Therefore, the liquid electrolyte may be used to cool the solar cell or vehicle engines in a liquid cooling manner. Further, the liquid electrolyte flow may improve power generation efficiency of the thermoelectric device.

FIG. 5 illustrates a cross-sectional view of one example of a thermoelectric system including a solar cell as a heat source.

Referring to FIG. 5, thermoelectric system may include the thermoelectric device and a solar cell 201 as the heat source thermally coupled to the thermoelectric device. The thermoelectric device may include the flow channel 110, the first and second electrodes 120, 130, and the electrolyte flow activator 140.

The solar cell 201 may be disposed on the first electrode 120. The solar cell 201 may transfer a waste heat resulting from conversion of a solar energy to an electrical energy to the first electrode 120. In FIG. 5, the first and second electrodes 120, 130 sandwich the flow channel 110 therebetween. However, the present disclosure is not limited thereto. That is, the arrangement of the first and second electrodes 120, 130 may not be limited specifically as described with reference to FIG. 1.

The thermoelectric device may be disposed on a rear face of the solar cell 201 to act as a cooler for the solar cell 201 using the liquid electrolyte in a liquid cooling manner. At the same time, the thermoelectric device may absorb the waste heat from the solar cell 201 and generate electrical power in addition to the power generated by the solar cell 201.

Substantially the same thermoelectric system as the thermoelectric system as shown in FIG. 5 is produced in a laboratory. AM 1.5G standard light source is irradiated to the solar cell 201 at an ambient temperature 15° C.

The temperature of an outer portion of the thermoelectric device, that is, the second electrode 130 is kept at 15° C., and the solar cell 201 has a surface temperature at 34° C. In this connection, it is checked that the temperature difference between the thermoelectric device and solar cell 201 is about 25.3° C., a current density is about 0.9 mA/cm².

As a comparison example 1, a device including only the solar cell 201 (hereinafter, a conventional solar cell) is produced. AM 1.5G standard light source is irradiated to the solar cell 201 at an ambient temperature 15° C. In this connection, a surface temperature of a solar cell, a current density J_{sc}, an open-circuit voltage V_{oc} and a photovoltaic efficiency Eff are measured over the irradiation time. The measurement results are shown in a following table 1.

TABLE 1

| | | Current | Open-circuit | Photovoltaic |
|---|---|---|---|---|
| Irradiation time | Temperature | density | voltage | efficiency |
| (min) | (° C.) | J_{sc} (mA/cm²) | V_{oc} (V) | Eff (%) |
| 10 | 47.2 | −4.75 | 4.32 | 14.1 |
| 20 | 53.9 | −4.77 | 4.22 | 13.7 |
| 30 | 58.5 | −4.80 | 4.14 | 13.4 |
| 40 | 61.0 | −4.78 | 4.10 | 13.2 |

Referring to the table 1, the surface temperature of the conventional solar cell increases over the light irradiation time. When the light irradiation time is about 40, the surface temperature thereof reaches about 61° C. As the surface temperature of the conventional solar cell increases, the open-circuit voltage decreases and a current density decreases. Further, As the surface temperature of the conventional solar cell increases, the photovoltaic efficiency decreases.

Compared to the conventional solar cell, the thermoelectric system including thermoelectric device in accordance with the present disclosure may cool the solar cell 201 using the thermoelectric device to suppress the increase in the surface temperature of the solar cell 201. Thus, the thermoelectric device may prevent performance deterioration of the solar cell 201 due to the temperature increase. At the same time, the thermoelectric device may generate additional power to remarkably improve the current density of the thermoelectric system.

In the present disclosure, the heat source 200 such as the solar cell or vehicle engine, requiring a cooler for a thermal management thereof may be combined with the thermoelectric device having the flow channel for the

liquid electrolyte flow to produce a hybrid thermoelectric system to achieve both of the efficient thermal management and further electrical energy harvesting. Further, the thermoelectric device may generate the power only using the waste heat emitted from the heat source 200 without a separate driver. The thermoelectric device may be easily coupled in series or parallel. Thus, the thermoelectric system 500 in accordance with the present disclosure may be employed by from a portable smaller device to an immobile larger device.

Although not shown in the figures, when the heat source 200 is implemented as a solar cell including two electrodes, the semiconductor and electrode may be stacked on the first electrode 120 on the thermoelectric device, thereby to simplify the structure of the heat source 200 in the thermoelectric system 500.

Moreover, the thermoelectric system 500 may further include a fixed-temperature keeping unit (not shown). The fixed-temperature keeping unit may act to keep a temperature of the liquid electrolyte in the thermoelectric device at a fixed level. Thus, cooling and power generation efficiencies may be improved.

The above description is not to be taken in a limiting sense, but is made merely for the purpose of describing the general principles of exemplary embodiments, and many additional embodiments of this disclosure are possible. It is understood that no limitation of the scope of the disclosure is thereby intended. The scope of the disclosure should be determined with reference to the Claims. Reference throughout this specification to “one embodiment,” “an embodiment,” or similar language means that a particular feature, structure, or characteristic that is described in connection with the embodiment is included in at least one embodiment of the present disclosure. Thus, appearances of the phrases “in one embodiment,” “in an embodiment,” and similar language throughout this specification may, but do not necessarily, all refer to the same embodiment.

What is claimed is:

1. A thermoelectric device comprising:
a closed-loop flow channel configured to allow a liquid electrolyte to circulate therein and therealong in one direction;
a first electrode disposed at a first position of the flow channel; and
a second electrode disposed at a second position of the flow channel, wherein the first and second positions are different,
wherein the liquid electrolyte has a redox reaction due to a temperature difference between the first electrode and the second electrode.

2. The thermoelectric device of claim 1, further comprising an electrolyte flow activator configured to activate the liquid electrolyte circulation along the flow channel.

3. The thermoelectric device of claim 1, further comprising an electrolyte cooler configured to cool the liquid electrolyte.

4. The thermoelectric device of claim 1, wherein the liquid electrolyte contains a hexacyanoferrate trivalent anion (Fe(CN)₆³⁻) and a hexacyanoferrate quadrivalent anion (Fe(CN)₆⁴⁻).

5. A thermoelectric system comprising:
a heat source; and
a thermoelectric device thermally coupled to the heat source,
wherein the thermoelectric device comprising:
a closed-loop flow channel configured to allow a liquid electrolyte to circulate therein and therealong in one direction, wherein the closed-loop flow channel is thermally-coupled to the heat source;
a first electrode disposed at a first position of the flow channel; and
a second electrode disposed at a second position of the flow channel, wherein the first and second positions are different,
wherein the liquid electrolyte has a redox reaction due to a temperature difference between the first electrode and the second electrode.

6. The system of claim 5, further comprising an electrolyte cooler thermally coupled to the thermoelectric device to cool the liquid electrolyte.

7. The system of claim 5, wherein the heat source is a solar cell, and the closed-loop flow channel acts to the solar cell using the liquid electrolyte.

8. The system of claim 5, wherein the heat source is a vehicle engine, and the closed-loop flow channel acts to the engine using the liquid electrolyte.
